(19) United States
(12) Patent Application Publication
(10) Pub. No.: US 2013/0332211 A1
(43) Pub. Date: Dec. 12, 2013

(54) METHOD OF CREATING WORK INSTRUCTION SHEET AND SYSTEM FOR SUPPORTING WORK INSTRUCTION SHEET CREATION

(71) Applicants: Nobuko Matsunaga, Aki-gun (JP); Masafumi Shinoda, Hiroshima-shi (JP); Masakazu Tsuji, Higashihiroshima (JP); Kenji Iida, Hiroshima-shi (JP)

(72) Inventors: Nobuko Matsunaga, Aki-gun (JP); Masafumi Shinoda, Hiroshima-shi (JP); Masakazu Tsuji, Higashihiroshima (JP); Kenji Iida, Hiroshima-shi (JP)

(73) Assignee: MAZDA MOTOR CORPORATION, Hiroshima (JP)

(21) Appl. No.: 13/824,296

(22) PCT Filed: Oct. 25, 2011
(86) PCT No.: PCT/JP2011/074553

§ 371 Date: Mar. 15, 2013

(30) Foreign Application Priority Data
Oct. 25, 2010 (JP) 2010-238557

(51) Int. Cl. G06Q 10/06

(52) U.S. Cl. CPC G06Q 10/0633
USPC 705/7.13

(57) ABSTRACT

It is an object to accurately perform a sequence of steps from setting of a process to creation of a work instruction sheet, based on design information. Provided is a work instruction sheet creation method which comprises: a preparation step of preparing specification information specifying what types of operation targets are included in each of a plurality of operation specifications, a setting step of setting, based on the specification information, process-related information with respect to each of the operation targets, to thereby create setting data including at least the operation targets, the operation specification and the process-related information; and a creation step of creating the work instruction sheet using the setting data.

### TECHNICAL FIELD

The present invention relates to a work instruction sheet creation method and a work instruction sheet creation support system for, in a situation where a plurality of operation specifications is set for a workpiece, creating a work instruction sheet for operation for a plurality of operation targets included in each of the operation specifications.

### BACKGROUND ART

There have heretofore been known a method of creating information for instruction on a process, and a system for supporting creation of such information. For example, JP 2002-086031A discloses a system for supporting a user to determine a paint color of a operating machine and create painting instruction information. This creation support system is configured to display a graphic depicting a plurality of painting areas of a operating machine, and, when a user designates at least one of the painting areas and selects a paint color of the designated area, display the designated painting area in a state in which it is colored with the selected paint color, while storing the designated painting area and the selected paint color in a memory.

Meanwhile, when a work instruction sheet is created by setting a process based on design information and verifying operational capability of the process, it is necessary to accurately reflect contents of the design information onto the work instruction sheet. However, during the course before completion of creation of the work instruction sheet from the design information, there are several steps, such as preparation of the design information, setting of the process, verification of the operational capability, and creation of the work instruction sheet. The existence of such a plurality of steps causes a problem that information is not adequately passed between the steps, or that, when a change is made in a design drawing, it is difficult to accurately reflect contents of design information onto a work instruction sheet, because the change is not accurately transmitted to the work instruction sheet, or the change is reflected onto an operation of only a part of the steps. Particularly, in cases where each of the steps is performed by a different operator, this problem becomes critical.

### SUMMARY OF THE INVENTION

The present invention has been made in view of the above point, and an object thereof is to accurately perform a sequence of steps from process setting to creation of a work instruction sheet, based on design information.

In order to solve the above problem, the present invention is directed to a work instruction sheet creation method for, in a situation where a plurality of operation specifications is set for a workpiece, creating a work instruction sheet for operation for a plurality of operation targets included in each of the operation specifications. The work instruction sheet creation method comprises: a preparation step of preparing specification information specifying what types of operation targets are included in each of the operation specifications; a setting step of setting, based on the specification information, process-related information with respect to each of the operation targets, to thereby create setting data including at least the operation targets, the operation specification and the process-related information; and a creation step of creating the work instruction sheet using the setting data.

The present invention is also directed to a work instruction sheet creation support system for, in a situation where a plurality of operation specifications is set for a workpiece, creating a work instruction sheet for operation for a plurality of operation targets included in each of the operation specifications. The work instruction sheet creation support system comprises: a client capable of accepting an input from a user and providing an output to a user; a storage device storing a work instruction sheet database having a plurality of process-related information settable, respectively, to various types of operation targets; and a server for performing a given processing, based on information input from the client. The server is operable to, upon receiving, from the client, an input of specification information specifying what types of operation targets are included in each of the operation specifications, generate setting data, using the operation targets and the operation specification; and, after reading, from the work instruction sheet database in the storage device, process-related information settable to the operation targets in the setting data, output the read process-related information to the client, wherein the server is operable to: upon receiving, from the client, an input of selection of either one of the settable process-related information, set the selected process-related information to the operation targets, and, after creating setting data including at least the operation targets, the operation specification and the process-related information, store the setting data in the storage device; and, upon receiving, from the client, an input requesting for the creation of the work instruction sheet, read the setting data from the storage device, and create the work instruction sheet.

In the present invention, based on the specification information specifying the operation targets with respect to each of the operation specifications, creation of the setting data, verification of operational capability, and creation of a work instruction sheet based on a result of the verification, are performed. This makes it possible to accurately perform the steps from process setting to creation of a work instruction sheet.

### BRIEF DESCRIPTION OF THE DRAWINGS

FIG. 1 is a block diagram of a work instruction sheet creation support system.

FIG. 2 is a flowchart of a work instruction sheet creation method.

FIG. 3 is a diagram illustrating 3D data of a body shell.

FIG. 4 is a diagram illustrating a operation specification drawing.

FIG. 5 is a diagram illustrating a hierarchical structure in the operation specification drawing.

FIG. 6 is a diagram illustrating text data obtained by outputting the operation specification drawing in a text form.

FIG. 7 is a diagram illustrating a specification matrix.

FIG. 8 is a diagram illustrating design data indicative of a change.

FIG. 9 is a flowchart of a data generation sub-substep.

FIG. 10 is a diagram illustrating process setting data.

FIG. 11 is a flowchart of a process setting dun-substep.

FIG. 12 is a flowchart of a theoretical verification step.

FIG. 13 illustrates a process tree for use in theoretical verification.

FIG. 14 is a diagram illustrating a virtual operation station.

FIG. 15 is a diagram illustrating a procedure drawing.

### DESCRIPTION OF EMBODIMENTS

Based on the drawings, an embodiment of the present invention will now be described in detail.

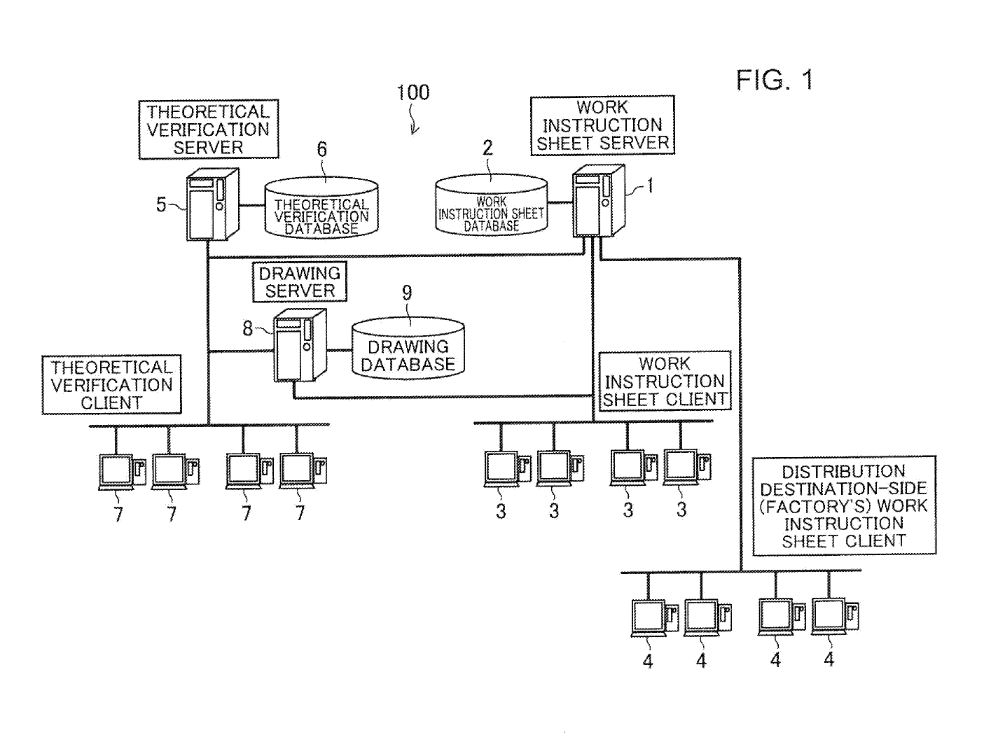

FIG. 1 is a block diagram illustrating a work instruction sheet creation support system according to one embodiment of the present invention by way of example only. The work instruction sheet creation support system 100 (hereinafter also referred to as “system 100”) is designed to support a user or operator to set a process from design information, and, after verifying operational capability of the process, create a work instruction sheet.

As illustrated in FIG. 1, the system 100 comprises: a work instruction sheet server 1; a theoretical verification server 5; a drawing server 8; a work instruction sheet database 2 connected to the work instruction sheet server 1; a theoretical verification database 6 connected to the theoretical verification server 5; a drawing database 9 connected to the drawing server 8; a plurality of work instruction sheet clients 3, 3, - - - connected to the work instruction sheet server 1 and the drawing server 8; a plurality of distribution destination-side work instruction sheet clients 4, 4, - - - connected to the work instruction sheet server 1; and a plurality of theoretical verification clients 7, 7, - - - connected to the work instruction sheet server 1, the theoretical verification server 5 and the drawing server 8. The work instruction sheet server 1, the theoretical verification server 5 and the drawing server 8 constitute a server. The work instruction sheet database 2, the theoretical verification database 6, the drawing database 9 and the work instruction sheet server 1 constitute a storage device. The work instruction sheet clients 3, 4 and the theoretical verification clients 7 constitute a client.

The work instruction sheet is composed of a procedure drawing presenting a operation procedure, and character information (including a table), and designed to describe a content and procedure of each operation. Specifically, the character information includes: “factory” in which each operation is performed; “project” (e.g., model name); “line” in a factory; “process”; “operation station” in a line; “operation”; “operation area” in a workpiece; “serial number” as an index for identifying a vehicle specification; “page”; “application” indicative of whether the range of application is all types of vehicles or a specific type of vehicle; “elemental operation”; “standard time” necessary for each operation; “control item” to be managed in order to assure quality (e.g., in taping, a requirement that a hole is fully closed up); “check item” to be inspected in order to realize the control item (e.g., in sealing, an inspection of a discharge amount of a sealer gun); “tools” (e.g., in sealing, a type of sealer gun); “materials” (e.g., in taping, a type of tape); and any other character information necessary for each operation. The term “process” means operation name expressed as a top-level concept. For example, it is “taping”. The term “operation” means operation name expressed as a middle-level concept. For example, it is “taping (underfloor)”. The term “elemental operation” means operation name expressed as a lower-level concept. For example, it is “cut and attach tape”. The character information is indicated in the form of a table or in the form of a sentence. The procedure drawing includes a 2D drawing, a 3D-PDF, and a moving image. In the specification of this application, the procedure drawing includes a moving image. The project, the factory, the line, the process, the operation, the operation area and the serial number are set as a work instruction sheet key (in some cases, the operation station is also included therein). A plurality of elemental operations each having the same work instruction sheet key are collected into one work instruction sheet and issued as an instruction.

The work instruction sheet client 3 is a client to be operated by a process setting operator. For example, it is composed of a personal computer. The work instruction sheet client 3 is operable to transmit an input operation from the process setting operator, to the work instruction sheet server 1, and display output data from the work instruction sheet server 1. The work instruction sheet database 2 stores therein data required for setting a process and creating a work instruction sheet. The work instruction sheet database 2 also stores therein, as a work instruction sheet database, a list of all operations and elemental operations to be performed in each factory and others, i.e., a list of process-related information. The work instruction sheet server 1 is operable, in response to receiving an input from each of the work instruction sheet clients 3, 3, - - - , to read the data in the work instruction sheet database 2, and process and store the read data, thereby supporting the process setting operator to set a process and create a work instruction sheet.

The theoretical verification client 7 is a client to be operated by a theoretical verification operator (who may be identical to the process setting operator). For example, it is composed of a personal computer. The theoretical verification client 7 is operable to transmit an input operation from the theoretical verification operator, to the theoretical verification server 5, and display output data from the theoretical verification server 5. The theoretical verification database 6 stores therein data required for performing theoretical verification. The theoretical verification database 6 also stores therein 3D data about equipment (usable operation equipment, etc.) and data about operators (human models for operators, etc.) in each factory, each line and each operation station, and data about a vehicle body (3D data about a workpiece) and data about operation targets, created by reading data from the drawing database 9 and concerting the read data into a format handleable by a theoretical verification tool. The theoretical verification server 5 is operable, in response to receiving an input from each of the theoretical verification clients 7, 7, - - - , to read the data in the theoretical verification database 6, and process and store the read data, thereby supporting the theoretical verification operator to perform theoretical verification of a process.

The drawing database 9 stores therein 3D data of each workpiece, and an aftermentioned specification matrix.

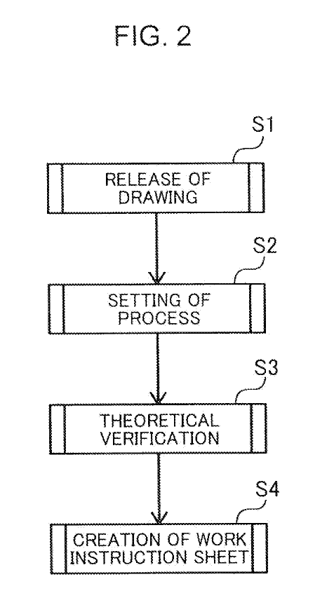

As illustrated in FIG. 2, a work instruction sheet creation method supported by this system 100 comprises: a drawing release step S1 of releasing design information; a process setting step S2 of setting a process based on the design information; a theoretical verification step S3 of verifying operational capability of the set process; and a work instruction sheet creation step S4 of creating a work instruction sheet based on a result of the verification. This work instruction sheet creation method will be described by taking, as an example, a taping operation for a vehicle body in a vehicle (automobile) painting process. The taping operation is intended to close up, with a tape, a hole unnecessary for a finished product, such as datum holes and drain holes for electrodeposition painting, formed in the vehicle body.

<Drawing Release Step>

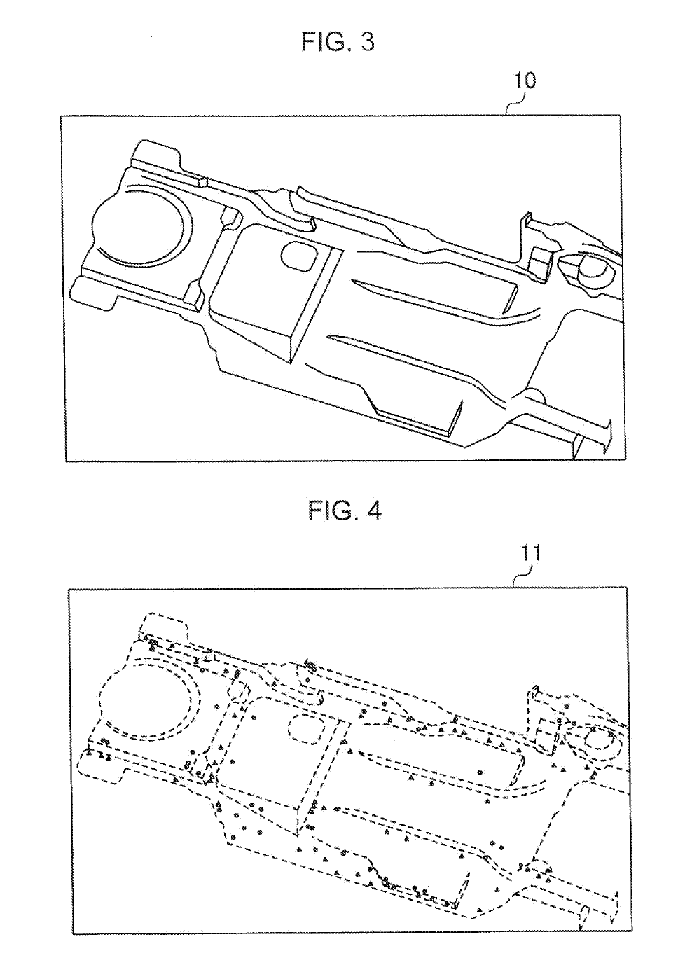

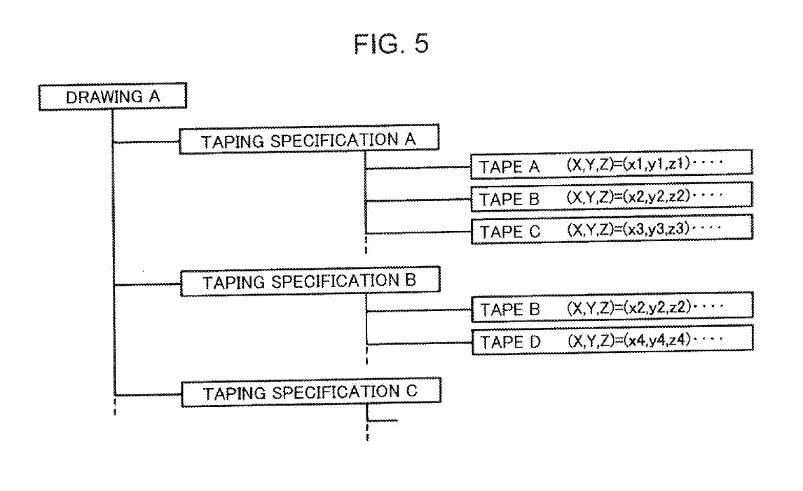

First of all, by use of a 3D-CAD, a design engineer creates 3D data about a workpiece, and creates a operation specification drawing in which a plurality of operation targets are arranged on the workpiece. In taping as an example of operation, a design engineer creates (designs) 3D data 10 about a body shell as a workpiece, as illustrated in FIG. 3. Then, with respect to each of a plurality of taping specifications, the design engineer arranges a plurality of tapes included in the taping specification, on the 3D body shell. In this way, a operation specification drawing 11 (FIG. 4) depicting taping layout is created. In the figure, each black circle mark indicates a tape arranged on an obverse surface of the body shell, and each black triangle mark indicates a tape arranged on a reverse surface of the body shell. The operation specification drawing 11 includes a plurality of taping specifications (e.g., “taping specification A”, “taping specification B”, “taping specification C”, - - - ). Each of the taping specifications is set by grouping taping data in each vehicle specification. The term “vehicle specification” means specifications in a certain type of vehicle, such as a domestic specification, a US specification, an EC specification, a 4-wheel drive specification and a 2-wheel drive specification. That is, each of the taping specifications corresponds to a respective one of the vehicle specifications. Each of the taping specifications includes a plurality of sets of taping data. Each of the sets of taping data indicates to which position of the vehicle body each tape should be attached, and comprises a label for identifying each taping (e.g., “tape A”, “tape B”, - - - ), and taping layout information in a coordinate system of the 3D-CAD data (e.g., XYZ coordinates). Although the description will be made based on an example where the layout information consists only of the coordinates, it is to be understood that it may include any other suitable information such as angle, in addition to the coordinates. That is, the operation specification drawing has a hierarchical structure as illustrated in FIG. 5. More specifically, on the side of a lower level with respect to the title “drawing A” of the operation specification drawing, each of the plurality of taping specifications: “taping specification A”, “taping specification B”, “taping specification C”, - - - , is connected. Then, on the side of a lower level with respect to each of the taping specifications, two or more of the tapes, for example, “tape A”, “tape B” and “tape C”, are connected. Under each of the tapes, its label and coordinate information are included.

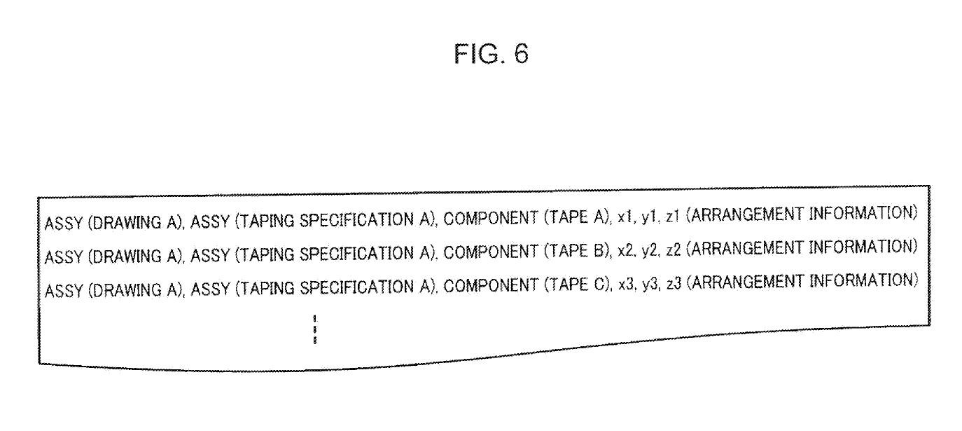

Then, the hierarchical structure and the taping layout information of the operation specification drawing is externally output in a text format, as illustrated in FIG. 6.

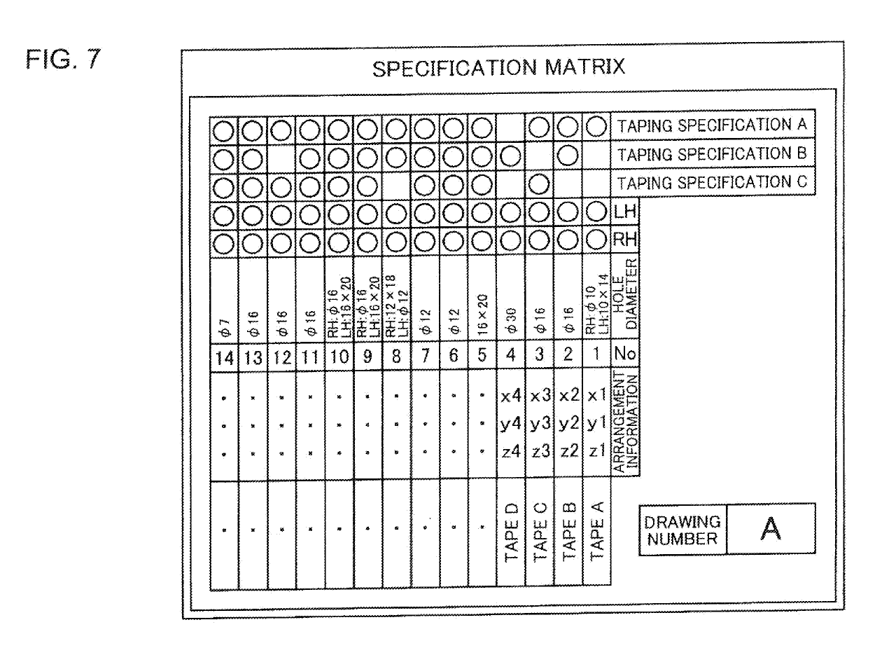

Subsequently, the text data is converted into tabular data as illustrated in FIG. 7. This conversion is performed, for example, by a macro-function of Excel. The tabular data is formed by summing up information about the presence or absence of each of a plurality of operation targets (a plurality of sets of a tape and a hole to be closed up by the tape) with respect to each of the taping specifications, in a tabular form, and will hereinafter be referred to as “specification matrix”. In the specification matrix, on an upper right side, respective titles of the taping specifications are described in a column direction. On a lowermost row, the tape labels are described. Further, on a row corresponding to each of the taping specifications, the presence or absence of each of the operation targets in the taping specification is indicated. Specifically, a white circle mark is described in a cell corresponding to the operation target included in the taping specification. For example, the taping specification A includes the tapes A, B, C, but it does not include the tape D. The taping specification B includes the tapes B, D, but it does not include the tapes A, C.

In the specification matrix, on a lower side of the rows indicative of the presence or absence of each of the tapes in respective ones of the taping specifications, information as to which of holes provided, respectively, on right and left sides of the vehicle body, a corresponding one of the tapes closes up, is indicated. In the table, a white circle mark existing in the row “LH” denotes that a hole to be closed up by the tape is provided on the left side of the vehicle body, whereas a white circle mark existing in the row “RH” denotes that a hole to be closed up by the tape is provided on the right side of the vehicle body. Further, on a lower side of the row for identifying right and left, a row describing a hole diameter is provided. That is, a diameter of a hole to be closed up by a corresponding one of the tapes is described. Further, on a lower side of the row for hole diameter, a row indicative of a serial number is provided. The serial number is assigned to each of the tapes. Further, on a lower side of each of the serial numbers, a row describing coordinates of a hole to be closed up by one of the tapes identified by the serial number is provided. In a lower right region of the specification matrix, a drawing number is described. In this way, the specification matrix is automatically generated from the operation specification drawing, for example, using the macro-function (alternatively, a program may be used). However, the “hole diameter” is not automatically input, but will be manually input later. The specification matrix constitutes specification information. In taping as an example of operation, the taping specification is equivalent to “operation specification”, and a set of each of the tapes and the holes (identified by a region (right or left), a hole diameter, and coordinates) to be closed up by the tape is equivalent to “operation target”. In the case where a plurality of holes are formed in left and right sides of the vehicle body, a combination of the holes and the tapes for closing up them makes up one operation target.

The specification matrix configured in this manner, a drawing cover sheet, and the operation specification drawing of 3D-CAD data, are released. A drawing number and a revision history (version number) are described on the drawing cover sheet. The revision history is increased every time a new drawing is released. The specification matrix, the drawing cover sheet, and the operation specification drawing in the form of 3D-CAD data are stored in the drawing database 9. The drawing release step is equivalent to “preparation step”.

<Process Setting Step>

Secondly, the process setting step will be described. The process setting step is designed to import the specification matrix, and create process setting data by setting process-related information to each operation target included in the specification matrix. The process setting step comprises a design data generation substep of generating design data from the specification matrix, and a process setting data generation substep of generating process setting data from the design data and setting process-related information to each operation target in the process setting data. The process setting step is equivalent to “setting step”, and the process setting data is equivalent to “setting data”.

<<Design Data Generation Substep>>

Firstly, in the specification matrix, a range of data to be formed as process setting data for use in process setting is selected. Specifically, the process setting operator operates the work instruction sheet client 3 to read a desired specification matrix from the drawing database 9 into the work instruction sheet client 3 via the drawing server 8. On the work instruction sheet client 3, the process setting operator sets a range of data in the specification matrix to be formed as process setting data, for example, using a macro-function of Excel. In response to this operation, each of the tapes is indicated by an identification number formed by combining the “serial number” and “L/R” in the specification matrix, for example, “L01”, “L02”, - - - , “R01”, “R02”, - - - . Further, on the assumption that information about each tape (identification number) and information about a corresponding hole, such as a hole diameter, are defined as one record (one operation target), belonging or non-belonging to each of the taping specification is set with respect to each operation target, and design data (CSV file) importable to the database is created. This design data is stored in the work instruction sheet server 1. In this way, design data usable for process setting in the work instruction sheet server 1 is created from the specification matrix.

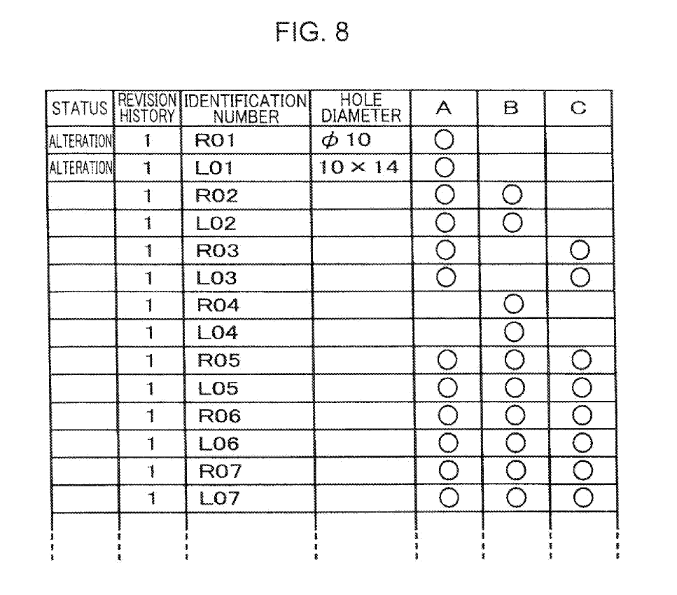

Then, the work instruction sheet server 1 imports the created design data, and, after ascertaining that the design data is not changed, registers it to the work instruction sheet database 2. Specifically, upon receiving an input for import of design data, from the process setting operator via the work instruction sheet client 3, the work instruction sheet server 1 reads the designated design data from the work instruction sheet server 1 and displays it on the work instruction sheet client 3 as new data. Further, the work instruction sheet server 1 reads design data having the latest version number, from the work instruction sheet database 2, and displays it on the work instruction sheet client 3 as old data. Then, upon receiving an input for ascertaining a change status, from the work instruction sheet client 3, the work instruction sheet server 1 ascertains a change status in the new and old design data by comparing them with each other, and causes the work instruction sheet client 3 to display the change status. FIG. 8 illustrates one example of this display. The change status includes “alteration” indicating that there is an alteration of attribute value or taping specification, “addition” indicating that a new identification number, i.e., operation target, is added, and “elimination” indicating that an existing identification number, i.e., operation target, is eliminated. The example illustrated in FIG. 8 shows one case where, in design data having a second-latest version number, a column for hole diameter was left blank space, whereas, in latest design data, two hole diameters “R01” and “L01” are input. Then, upon receiving an input for registration, from the work instruction sheet client 3, the work instruction sheet server 1 stores design data including information about the change status, in the work instruction sheet database 2, as design data having a version number obtained by adding 1 to a previously-latest version number (i.e., a new latest number). In this way, design data including change status information is stored (overwritten) in the work instruction sheet database 2.

<<Process Setting Data Creation Substep>>

Secondly, process setting data corresponding to the design data is created. The process setting data creation substep comprises a data generation sub-substep of generating process setting data, and a process setting sub-substep of setting process-related information to each operation target in the process setting data.

The process setting data is created with respect to each project, each process, each drawing number and each factory. In the process setting data, process-related information, such as “operation area”, “operation”, “elemental operation”, “operation station”, “serial number”, “page”, “application” and “taping specification”, is set with respect to each operation target (set of the identification number and the hole diameter).

<<<Data Generation Sub-Substep for Process Setting Data>>>

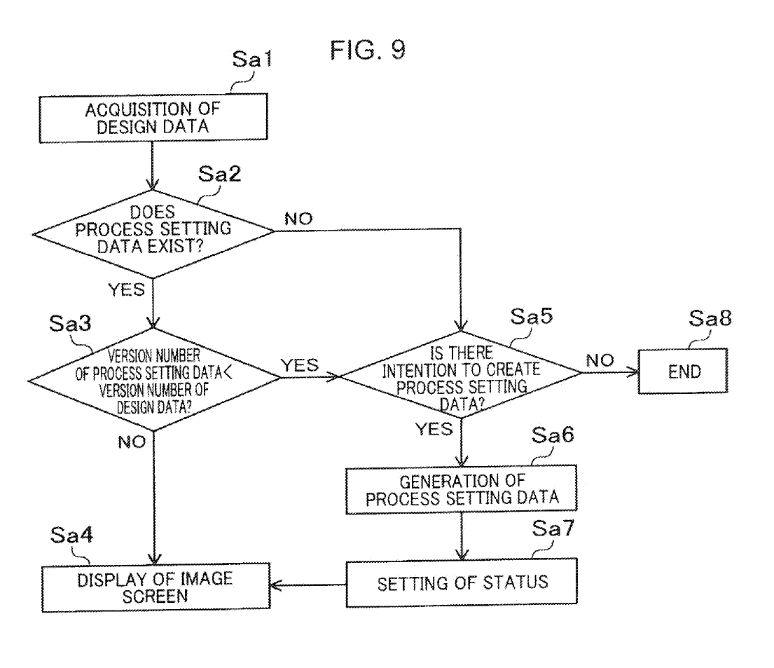

FIG. 9 is a flowchart of the data generation sub-substep. In the data generation sub-substep, when new design data is created, process setting data corresponding to the new design data is generated. First of all, in Step Sa1, the work instruction sheet client 3 presents a given input screen to the process setting operator, and prompts the process setting operator to input information about project, process, drawing number and factory. In response to an input of the information about project, process, drawing number and factory, from the process setting operator, the work instruction sheet client 3 transmits the information to the work instruction sheet server 1. Upon receiving the input of information about project, process, drawing number and factory, the work instruction sheet server 1 retrieves and acquires design data corresponding to the input information, from the work instruction sheet database 2.

Subsequently, in Step Sa2, the work instruction sheet server 1 retrieves process setting data corresponding to the input information about project, type, drawing number and factory, from the work instruction sheet database 2, and ascertains whether or not the corresponding process setting data exists. When the corresponding process setting data exists (YES), the flow advances to Step Sa3. On the other hand, when the corresponding process setting data does not exist (NO), the flow advances to Step Sa5.

In the Step Sa5, the work instruction sheet server 1 transmits to the work instruction sheet client 3 a response indicating that process setting data having a version number corresponding to that of the design data does not exist. The work instruction sheet client 3 displays an image screen for prompting the process setting operator to respond to a query as to whether or not he/she intends to create process setting data. When an input indicative of intention to create process setting data is made by the process setting operator via the work instruction sheet client 3 (YES), the flow advances to Step Sa6. On the other hand, when an input indicative of no intention to create process setting data is made by the process setting operator via the work instruction sheet client 3 (NO), the flow advances to Step Sa8. In the Step Sa8, the flow is terminated.

In the Step Sa6, the work instruction sheet server 1 generates process setting data having a version number corresponding to that of the design data. Generally, the situation where the corresponding process setting data does not exist corresponds to a situation where only design data is created and corresponding process setting data has not been created. Thus, a version number of the design data is 0. Therefore, process setting data having a version number of 0 is generated. The process setting data having a version number of 0 consists only of information about “identification number”, “hole diameter” and “taping specification” which can be acquired from the design data, because contents of a process have not yet be set.

In Step Sa7, the work instruction sheet server 1 sets a process setting data change status to the created process setting data. The process setting data having a version number of 0 is completely new data, because it does not have any existing process setting data to be compared therewith. Details of Step Sa7 will be described later.

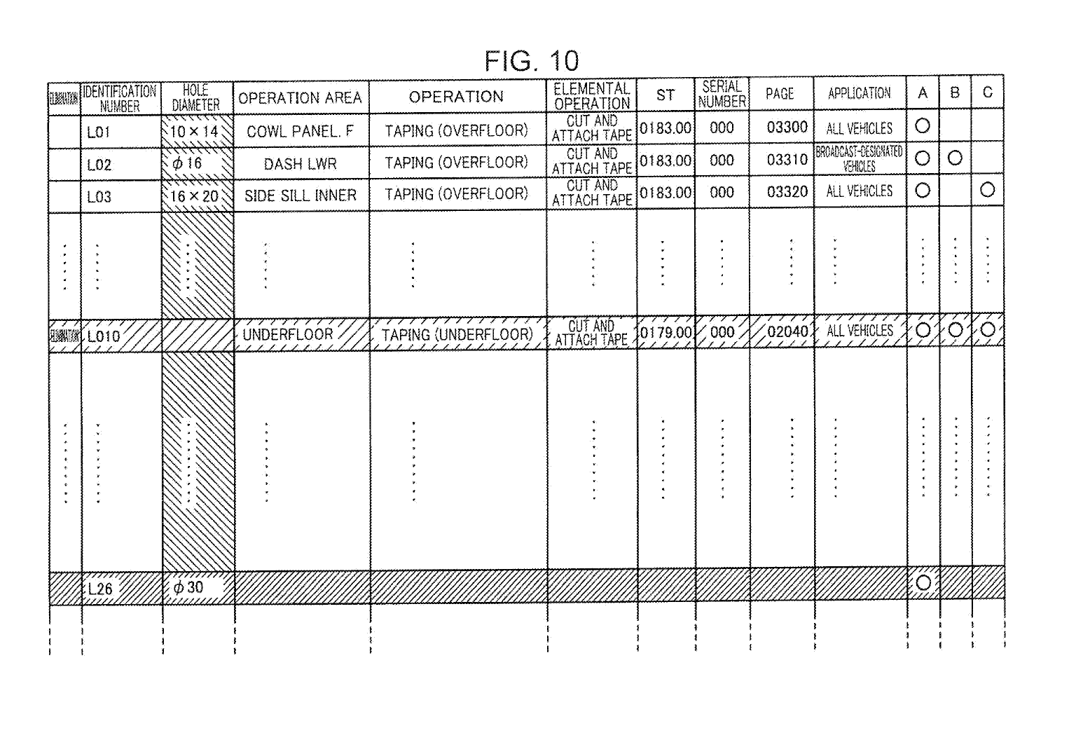

Then, the flow advances to Step Sa4. In the Step Sa4, the work instruction sheet server 1 causes the work instruction sheet client 3 to display process setting data like a table illustrated in FIG. 10, wherein columns “operation area”, “operation”, “elemental operation”, “operation station (ST)”, “serial number”, “page” and “application” are left blank space. In the process setting data having a version number of 0, the above columns are left blank space, because information about “operation area”, “operation”, “elemental operation”, “operation station”, “serial number”, “page” and “application” has not been set.

Meanwhile, in the Step Sa3 to which the flow advances when the corresponding process setting data exists, the work instruction sheet server 1 compares a version number of the acquired design data with a version number of the process setting data, and determines whether or not the version number of the design data is greater than the version number of the process setting data. Then, when the design data has a greater version number (YES), it is judged that the process setting data is older than the design data, and the flow advances to the Step Sa5. On the other hand, when the version number of the design data is equal to or less than the version number of the process setting data (generally, the version number of the design data is equal to the version number of the process setting data) (NO), it is judged that the process setting data having the same version number as that of the design data already exists, and the flow advances to the Step Sa4. In the Step Sa4, the work instruction sheet server 1 causes the work instruction sheet client 3 to display the existing process setting data.

As mentioned above, in the Step Sa5, the process setting operator is inquired as to whether or not he/she intends to create process setting data.

In the Step Sa6, the work instruction sheet server 1 makes a copy of the latest process setting data, and reflects a change in the new design data to the copy to generate process setting data having a version number obtained by adding 1 to the version number of the latest process setting data. For example, when the design data has a change in terms of addition of a operation target, this operation target is also added to the process setting data. Further, when the design data has a change in terms of addition of a taping specification, this taping specification is also added to the process setting data. When the design data has a change in terms of alteration of data contents (e.g., change or write-in of hole diameter), this content is also changed in the process setting data. When the design data has a change in terms of elimination of a operation target or vehicle specification, this operation target or vehicle specification is also eliminated from the process setting data.

Then, in the Step Sa7, the work instruction sheet server 1 registers a change status, such as the addition, the content alteration and the elimination, onto the process setting data.

Subsequently, in Step Sa4, the work instruction sheet server 1 causes the work instruction sheet client 3 to display new process setting data as illustrated in FIG. 10. Generally, in existing process setting data, the process-related information such as “operation area” has already been input through the aftermentioned process setting sub-substep. In new process setting data, any record having no change is formed by directly copying a corresponding content of a previously-latest process setting data. Therefore, in process setting data having a version number of 1 or more, as for any record having no change, the process-related information such as “operation area” exists at this timing. Based on the change status registered on the process setting data, the work instruction sheet client 3 displays the process setting data in a color-coded manner so as to allow a changed area in the process setting data to be recognized. For example, the addition, the content alteration and the elimination are color-coded by red, orange and gray, respectively. In FIG. 10, these are distinguished from each other by means of hatching. This makes it possible to enhance visibility of changes in process setting data.

<<<Process Setting Sub-Substep>>>

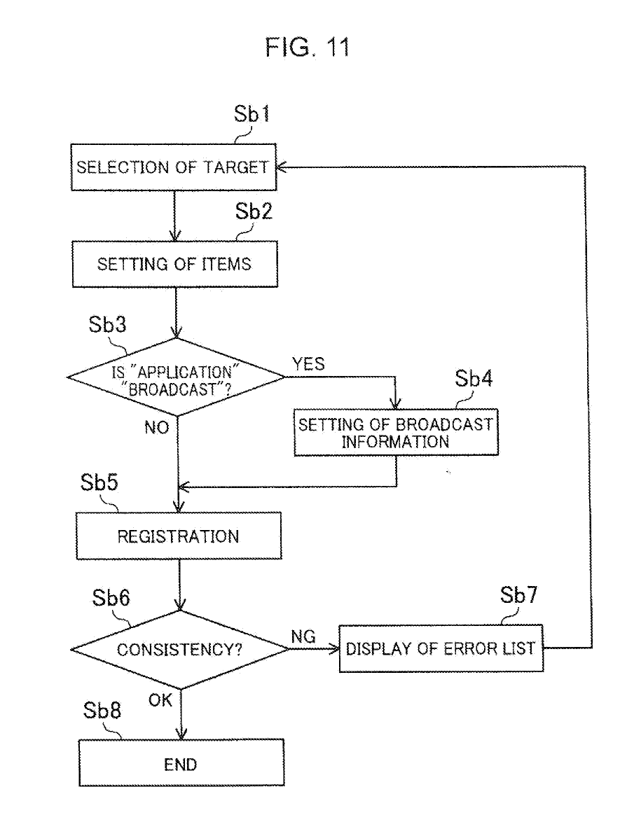

Subsequently, process-related information is specifically set with respect to each operation target in the new process setting data. More specifically, as for process setting data having a version number of 0, process-related information is set to all operation targets therein, because a process has not yet been set. On the other hand, as for process setting data having a version number of 1 or more, process-related information is set to each operation target having a change. The following description will be made about process setting for process setting data having a version number of 1 or more, illustrated in FIG. 10. FIG. 11 is a flowchart of the process setting sub-sub step.

First of all, in Step Sb1, the work instruction sheet server 1 causes the work instruction sheet client 3 to display a process setting screen, as illustrated in FIG. 10. On this screen, process setting data having the same display format as that in FIG. 10, and an input box for inputting process-related information, are displayed. An input item includes “operation area”, “operation”, “elemental operation”, “operation station (ST)”, “serial number”, “page”, and “application”. Each of the items “operation area”, “operation”, “elemental operation” and “operation station” is standardized, and registered on the work instruction sheet database in the work instruction sheet database 2. That is, the work instruction sheet server 1 reads a setting list for these items from the work instruction sheet database, and causes the work instruction sheet client 3 to display the list in a given display format such as a combo box. The process setting operator selects a operation target (identification number) from the process setting data, via the work instruction sheet client 3. For example, a newly added operation target is selected.

Then, in Step Sb2, the process setting operator selects setting contents for “operation”, “elemental operation”, “operation station (ST)” and “application”, from the combo boxes, and inputs “serial number” and “page”. Subsequently, in Step Sb3, it is determined whether or not “application” is “broadcast”. When “application” is “broadcast” (YES), the flow advances to Step Sb4, wherein broadcast information is set. On the other hand, when “application” is not “broadcast”, i.e., “all vehicles”, the flow advances to Step Sb5. The term “broadcast information” means information to be broadly distributed to operators in a factory via an information board (called “broadcast”) moved along a production line together with vehicles.

In Step Sb5, when the process setting operator pushes a “registration” button via the work instruction sheet client 3, the work instruction sheet server 1 performs consistency checkup in Step Sb6. In the consistency checkup, it is checked whether there is consistency, for example, a situation where only a content of “page” is changed although contents of “operation area”, “operation”, “elemental operation” and “serial number” are unchanged, or a situation where broadcast information is set although “application” in the selected operation target is “all vehicle”. When there is some inconsistency (NO), the work instruction sheet server 1 reads an error list stored in the work instruction sheet database 2, and causes the work instruction sheet client 3 to display it, in Step Sb6. When the error list is displayed, the process setting operator returns to the Step Sb1 and restarts the selection of a operation target. On the other hand, there is consistency (YES), the work instruction sheet server 1 stores the new process setting data in the work instruction sheet database 2. Generally, in this case, the same version number as that of latest design data is assigned to the new process setting data. In this way, process setting data is created.

Subsequently, according to operation of the process setting operator, the work instruction sheet client 3 displays an output screen for outputting the process setting data in the form of data readable into a theoretical verification tool (inputtable data). The work instruction sheet client 3 prompts the process setting operator to input information about project and factory. When the process setting operator inputs the information, the work instruction sheet client 3 transmits the information to the work instruction sheet server 1. The work instruction sheet server 1 retrieves the latest process setting data from the work instruction sheet database 2, and causes the work instruction sheet client 3 to display the retrieved process setting data. Then, when the process setting operator pushes an output button on the screen, the process setting data is rewritten into inputtable data which is readable into a theoretical verification tool. The inputtable data is stored in the work instruction sheet server 1.

<Theoretical verification Step>

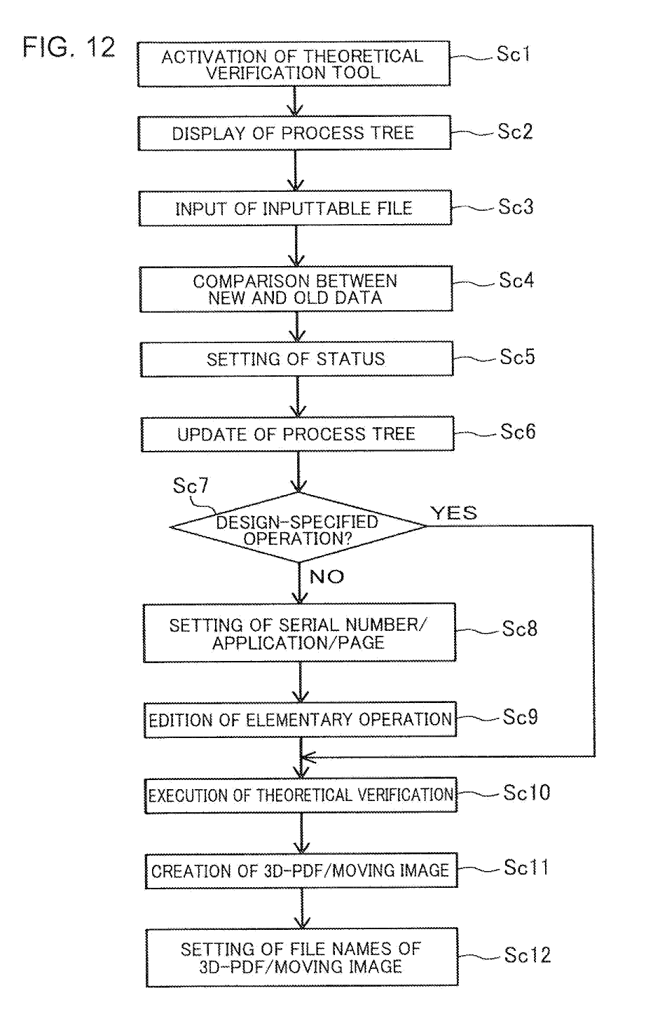

Next, the theoretical verification step will be described. FIG. 12 illustrates a flowchart of the theoretical verification step. The theoretical verification step is performed using a theoretical verification tool. For example, the theoretical verification tool may be commercially available eM-Planner (produced by Siemens PLM). The theoretical verification step is equivalent to “verification step”.

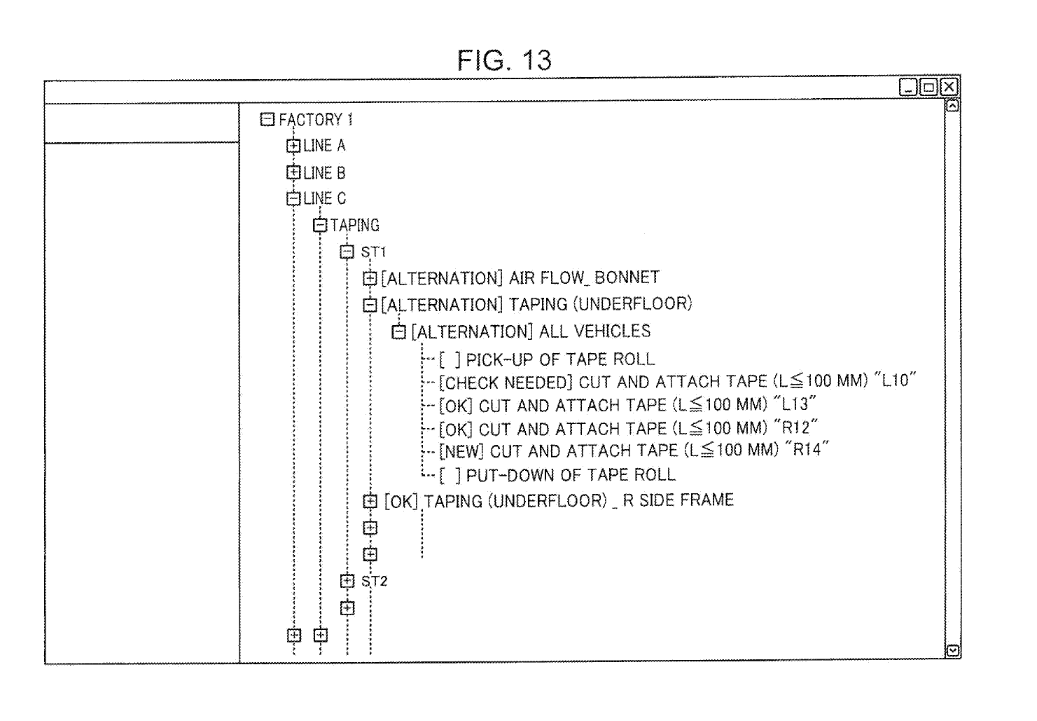

The theoretical verification tool manages information about a configuration of a operation station of a factory, and process-related information about a operation to be performed in the operation station and others, in the form of a process tree (FIG. 13) having a hierarchical structure. The factory operation station configuration information is defined by “factory”, “line”, “process” and “operation station”. The process-related information includes “operation”, “operation area”, “serial number” and “elemental operation”, and tapes in the operation targets (identification numbers such as L10 and L13) are allocated at the same level as an elemental operation (e.g., cut and attach tape) under a specific operation station, by the process setting. In the process setting data (inputtable data) and the process tree, the same “project”, “factory”, “operation station”, “operation”, “operation area”, “serial number”, “elemental operation” and “operation targets” are used as key items.

Upon activation of the theoretical verification tool by the theoretical verification operator via the theoretical verification client 7 (Step Sc1), the theoretical verification server 5 retrieves and reads the latest version of existing process tree from the theoretical verification database 6. During this operation, when no process tree exists in the theoretical verification database 6, a process tree is generated using data of the work instruction sheet database in the work instruction sheet database 2. The theoretical verification server 5 causes the theoretical verification client 7 to display the process tree (Step Sc2).

Then, in Step Sc3, the theoretical verification operator inputs the inputtable data (process setting data) via the theoretical verification client 7. Upon receiving the input of the inputtable data from the theoretical verification operator, the theoretical verification server 5 reads corresponding inputtable data from the theoretical verification database 6. With respect to each of the key items, the theoretical verification server 5 compares the process setting data with the process tree (Step Sc4) to check a change status. Then, the theoretical verification server 5 sets a change status (Step Sc5), and updates and displays the process tree, as illustrated in FIG. 13 (Step Sc6). For example, the status to be set includes “OK”, “alteration”, “new” and “check needed”. The status “OK” indicates a situation where corresponding items exist in both the process tree and the process setting data, and there is no change in content thereof. The status “alteration” indicates a situation where although corresponding items exist in both the process tree and the process setting data, there is a change in content thereof. The status “new” indicates a situation where some one or more items exist only in the process setting data without existing in the process tree. For example, it indicates a situation where the one or more items are newly set. The status “check needed” indicates a situation where some one or more items exist only in the process tree without existing in the process setting data. For example, it indicates a situation where the one or more items are eliminated.

Then, the theoretical verification operator sets a process of a operation which is not specified by design information. That is, process setting data is based on released design information, and therefore includes only information about a operation specified by the design information. However, in a vehicle (automobile) production process, in addition to a operation specified by the design information (hereinafter referred to as “design-specified operation”), there is a operation which is not specified by the design information, such as a operation of cleaning or opening vehicle doors (hereinafter referred to as “non-design-specified operation”). The process tree manages not only a design-specified operation but also a non-design-specified operation. As for the design-specified operation, information set in the drawing release step and the process setting step is reflected onto a process tree, so that it cannot be edited by the theoretical verification tool. That is, information about the design-specified operation can be edited only through the drawing release step and the process setting step. This makes it possible to prevent information about design operation in respective steps from becoming inconsistent due to edition of the information in various steps. On the other hand, information about the non-design-specified operation is set using the theoretical verification tool. This information about the non-design-specified operation is equivalent to “non-design-specified operation target”.

Then, the theoretical verification operator determines whether a operation is the design-specified operation or the non-design-specified operation (Step Sc7). When an item selected in the process tree in FIG. 11 relates to the design-specified operation (YES), the theoretical verification server 5 causes the theoretical verification client 7 to display attribute values of the selected item in a non-editable state. On the other hand, when the selected item relates to the non-design-specified operation (NO), the flow advances to Step Sc8. In Step Sc8, the theoretical verification server 5 causes the theoretical verification client 7 to display a box for allowing attribute values of the selected item to be input therethrough, to prompt the theoretical verification operator to input the attribute values. For example, an inputtable attribute value includes “page”, “serial number” and “application”. Then, the theoretical verification operator inputs required information into the input box, so that process-related information about the non-design-specified operation is set and registered. Further, in Step Sc9, the theoretical verification operator performs edition of the information about the non-design-specified operation, such as addition and/or elimination, according to need.

In this way, the information about the non-design-specified operation is set to the process tree. Consequently, process setting in the process tree is fixed. The obtained process tree is stored in the theoretical verification database 6.

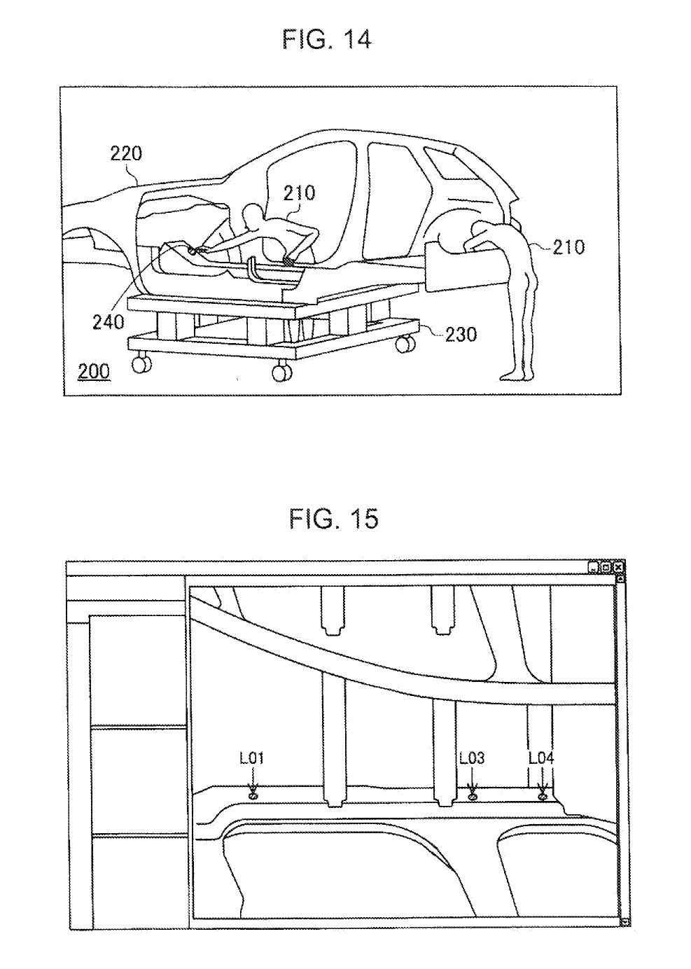

Subsequently, in Step Sc10, theoretical verification is executed. The theoretical verification is performed using 3D data. Specifically, the theoretical verification server 5 reads, from the theoretical verification database 6, equipment data, human data, vehicle body data (e.g., 3D data of the body shell as illustrated in FIG. 3) and operation target data (in taping as an example of operation, a operation specification drawing equivalent to that in FIG. 4) each corresponding to a operation station selected by the theoretical verification operator. The theoretical verification server 5 combines the read data to form a 3D virtual operation station. FIG. 14 illustrates one example of the virtual operation station. The virtual operation station 200 comprises two operator models 210, 210, a vehicle model 220, a carrier model 230 as the equipment, and a tape model 240 as the operation target. The theoretical verification operator can operate the theoretical verification client 7 to move the operator models 210, 210 in the virtual operation station, or rotates the virtual operation station, or increases/reduces a magnification of the virtual operation station. The theoretical verification operator verifies operational capability through an operation of causing the operator model 210 to perform an elemental operation for the tape model 240 in the virtual operation station.

As a result of the verification, when it is determined that the elemental operation should be performed according to a specific operation procedure in view of at least one of enhancement in operational capability and quality assurance, a 3D-PDF file and/or a moving image file indicative of the operation procedure is created as a procedure drawing, in Step Sc11. Specifically, the theoretical verification operator reads 3D data of a vehicle body from the drawing database 9 via the drawing server 8. Then, the read 3D data is captured in a 3D-PDF file, and, if needed, information is added to the 3D-PDF file. Alternatively, a 3D-PDF file and/or a moving image may be created using the virtual operation station used in the verification. FIG. 15 illustrates one example of the procedure drawing. The procedure drawing in FIG. 15 illustrates a vehicle body and tapes. The 3D-PDF file and/or the moving image are stored in the work instruction sheet server 1. Then, in Step Sc12, file names thereof are registered at a corresponding series number in the process tree, and stored in the theoretical verification database 6. As a result of the verification, when it is determined that the elemental operation is impracticable, a content of the verification is fed back to the design engineer.

Then, the theoretical verification operator operates the theoretical verification client 7 to output process setting contents to be specified by a work instruction sheet, from the process tree. The process setting contents are output for the purpose of creation of a work instruction sheet, in units of any item (e.g., operation station) in the process tree. During this operation, it is checked whether there is an overlap in work instruction sheet key. When there is the overlap, an error message is displayed to prompt the theoretical verification operator to make a correction. When there is no overlap, the process setting contents are output. The output data (hereinafter referred to as “post-verification data”) is stored in the work instruction sheet server 1.

<Work Instruction Sheet Creation Step>

Next, the work instruction sheet creation step will be described. The work instruction sheet creation step is designed to create a work instruction sheet using a process tree after the theoretical verification, and a procedure drawing created during the theoretical verification. The work instruction sheet creation step comprises: a verification result data import substep of importing process setting contents of a process tree; a work instruction sheet generation substep of generating a work instruction sheet based on the imported process setting contents; a work instruction sheet edition substep of editing contents of the generated work instruction sheet; a consistency confirmation substep of confirming consistency of the created work instruction sheet; and an authorization substep of authorizing the work instruction sheet after the consistency confirmation. The work instruction sheet creation step is equivalent to “creation step”.

<<Verification Result Data Import Substep>>

First of all, process setting contents of a process tree, and a theoretical verification result, are imported. According to operation of the work instruction sheet client 3 by the process setting operator, the work instruction sheet server 1 reads designated post-verification data from the work instruction sheet server 1, and causes the work instruction sheet client 3 to display a list of the post-verification data. The process setting operator operates the work instruction sheet client 3 to select one post-verification data to be imported from the list.

The work instruction sheet server 1 compares the imported post-verification data with the work instruction sheet database stored in the work instruction sheet database 2. When the post-verification data includes a record which does not exist in the work instruction sheet database, the process setting operator verifies whether it is necessary to update the work instruction sheet database, for example, due to a situation where a new combination of a operation station and a operation occurs, or whether the process tree is wrong. In the former case, the work instruction sheet database in the work instruction sheet database 2 is corrected and updated through a system administrator. In the latter case, the process tree is corrected using the theoretical verification tool, and new post-verification data is output again.

In addition, the work instruction sheet server 1 compares the imported post-verification data with process setting data stored in the work instruction sheet database 2. When there is a difference between the post-verification data and the process setting data, the process setting data is prioritized over the post-verification data. Thus, the process tree is corrected by the process setting operator, using the theoretical verification tool, and new post-verification data is output again.

When the post-verification data is consistent with the work instruction sheet database and the process setting data, the post-verification data is imported.

<<Work Instruction Sheet Generation Substep>>

Secondly, a work instruction sheet is generated based on the imported post-verification data. Work instruction sheet data prepared by copying the work instruction sheet database is preliminarily stored in the work instruction sheet database 2. With respect to each work instruction sheet key included in the imported post-verification data, the latest version of record for work instruction sheet data corresponding to the work instruction sheet key is extracted from the work instruction sheet database 2. When there is work instruction sheet data kept in a state just after being prepared from the work instruction sheet database, the work instruction sheet server 1 sets “page”, “application”, “elemental operation”, “link file name” (file names of the 3D-PDF file and/or the moving image file) to the work instruction sheet data according to input from the process setting operator, to generate new work instruction sheet data, and stores the new work instruction sheet data in the work instruction sheet database 2.

<<Work Instruction Sheet Edition Substep>>

Next, required items are additionally set for the generated work instruction sheet data. That is, among the work instruction sheet data, control items, check items and others which are not set from the post-verification data are set.

Then, when the created work instruction sheet data is output, a work instruction sheet will be output which comprises character information explaining each operation procedure, and a drawing such as a 2D drawing, a 3D-PDF and/or a moving image.

<<Consistency Confirmation Substep>>

Next, according to input from the process setting operator, the work instruction sheet server 1 checks consistency in the work instruction sheet data (e.g., whether or not broadcast information is set despite that “application” is “all vehicle”), and compares the work instruction sheet data and the process setting data to check whether contents set based on the process setting data are adequately reflected onto the work instruction sheet.

<<Authorization Substep>>

The work instruction sheet created in this manner is authorized by a plurality of responsible persons. Specifically, a user having authority logins via the work instruction sheet client 3, and reads work instruction sheet data in the work instruction sheet database 2 to perform a processing depending the authority. The work instruction sheet data having registered information about the processing is stored in the work instruction sheet database 2. The processing is performed in turn from a downstream responsible person to an upstream responsible person, and the work instruction sheet is finally authorized. The authorized work instruction sheet is permitted to be distributed.

When the distribution of work instruction sheet is permitted, a user can view the work instruction sheet depending on his/her authority. That is, a user can retrieve a desired work instruction sheet from the work instruction sheet database 2 via the distribution designation-side work instruction sheet client 4, and view the retrieved work instruction sheet.

Thus, in the above embodiment, based on the specification matrix, the step of setting a process, the step of verifying operational capability and the step of creating a work instruction sheet are performed in order. The setting of a process, the verification of operational capability and the creation of a work instruction sheet are substantially connected to each other through the specification matrix, so that a change in the specification matrix is accurately transmitted to the work instruction sheet. In particular, even when each step is performed by a different operator, information of the specification matrix can be accurately transmitted to adequately create the work instruction sheet.

Specifically, a specification matrix is prepared in which each operation target (set of a tape and a hole to be closed up by the tape) is specified with respect to each of a plurality of taping specifications. Thus, even in the case where there are a plurality of types of tapes, it can be easily recognized what types of tapes are included in each of the taping specifications.

As above, each operation target is specified with respect to each of the taping specifications. Thus, when any of the operation targets and the taping specification is changed, the change can be easily recognized.

Further, because each operation target is specified with respect to each of the taping specifications, it becomes possible to easily recognize whether each operation target is a common one among the taping specifications, or is an individual one for each of the taping specifications. If it can be known whether each operation target is a common one or an individual one, the subsequent process setting and theoretical verification can be simplified.

Then, based on the specification matrix, the process-related information is set with respect to each operation target. Thus, the process-related information can be thoroughly set for all operation targets included in the specification matrix. Further, the setting data is created based on the design data created based on the specification matrix, which means that the setting data is created indirectly based on the specification matrix. Therefore, in the setting data, it is clear what types of operation targets are included in each of the taping specifications.

In the theoretical verification, the verification of operational capability is performed based on the setting data. Thus, the verification can be performed thoroughly for all operation targets set in the process setting step. The process setting step is created based on the specification matrix. Thus, the verification will be performed for all operation targets included in the taping specification. Further, because it is clear what types of operation targets in the setting data are included in each of the taping specifications, it becomes possible to easily verify operational capability of the plurality of operation targets included in the same taping specification.

In the theoretical verification, during verification of operational capability, it is determined what kind of operation procedure can promote operation adequacy. Thus, it is efficient to create a operation procedure determined by the verification, as a procedure drawing.

In the work instruction sheet creation step, the work instruction sheet is created using the taping specification, the operation targets and the process-related information in the post-verification data, and the procedure drawing. The taping specification, the operation targets and the process-related information are information created through the process setting based on the specification matrix, i.e., created indirectly based on the specification matrix. Thus, information of the specification matrix can be accurately reflected onto the work instruction sheet. Further, the work instruction sheet is created using the procedure drawing created through the theoretical verification. Thus, the procedure drawing reflecting a verification result in the theoretical verification can be appended to the work instruction sheet. Further, the created procedure drawing is stored in a manner associated with the operation targets, the taping specification and others subjected to the theoretical verification. Thus, it becomes possible to easily read a required procedure drawing during creation of the work instruction sheet.

When the specification matrix is changed, any change in the operation targets and the taping specification is extracted as a change status, during the process setting. Thus, a process can be thoroughly set and changed according to the change in the specification matrix.

During the theoretical verification, a process for a non-design-specified operation is additionally set, and then operational capability is verified. Thus, the verification of operational capability can be performed in a situation close to an actual operation site, which makes it possible to enhance the accuracy of operational capability.

In a situation where as a result of the theoretical verification, it becomes necessary to correct the work instruction sheet database, the work instruction sheet database can be updated as needed, and subsequently the process setting, the theoretical verification and others can be performed using the updated work instruction sheet database.

Although the above embodiment has been described based on the taping operation as an example, the present invention is not limited thereto. For example, the present invention may be applied to a grommet fitting operation for closing up a hole by a resin component, a sealing operation for filling up a gap by a sealer, or an undercoating operation for applying antirust coat.

In the above embodiment, the server, the database and the client are provided as a plurality of separate groups depending on functionalities. Alternatively, the work instruction sheet creation support system may comprise one server, one database, and one type of client.

In the above embodiment, a process tree is generated from the process setting data, and the theoretical verification is performed using the process tree. Then, when it becomes necessary to correct a process, the process tree is corrected. Then, post-verification data is created from the process tree, and the work instruction sheet is created using the post-verification data. That is, the work instruction sheet is created from the post-verification data which is substantially equal to the process setting data but is converted into a different format. However, the present invention is not limited thereto. For example, the system may be configured such that the work instruction sheet is created using the process setting data stored in the work instruction sheet database 2. In this case, a result of the theoretical verification is directory reflected onto the process setting data by correcting the process setting data stored in the work instruction sheet database 2. That is, as long as the work instruction sheet is created substantially based on the process setting data, any configuration may be employed.

It should be understood that the above embodiment is essentially a preferred example of the present invention, and is not intended to restrict a scope of application and use thereof.

Lastly, based on the contents of the above embodiment described as one example of the present invention, features and advantageous effects of the present invention will be outlined below.

The present invention is directed to a work instruction sheet creation method for, in a situation where a plurality of operation specifications is set for a workpiece, creating a work instruction sheet for operation for a plurality of operation targets included in each of the operation specifications. The work instruction sheet creation method comprises: a preparation step of preparing specification information specifying what types of operation targets are included in each of the operation specifications; a setting step of setting, based on the specification information, process-related information with respect to each of the operation targets, to thereby create setting data including at least the operation targets, the operation specification and the process-related information; and a creation step of creating the work instruction sheet using the setting data.

In the above method, firstly, in the preparation step, specification information is prepared which specifies what types of operation targets are included in each of the operation specifications. Thus, even in the case where there are a plurality of types of operation targets, it can be easily recognized what types of operation targets are included in each of the operation specifications. The specification information is a part of design information. As above, the plurality of operation targets are specified with respect to each of the operation specifications. Thus, when any of the operation targets and the operation specification is changed, the change can be easily recognized by comparing operation specifications before and after the change. Further, it becomes possible to easily recognize whether each operation target is a common one among the operation specifications, or is an individual one for each of the operation specifications. If it can be known whether each operation target is a common one or an individual one, the subsequent process setting and theoretical verification can be simplified.

Then, in the setting step, based on the specification information, the process-related information is set with respect to each operation target. Thus, the process-related information can be thoroughly set for all operation targets included in the specification information. Further, the setting data is created based on the specification information. Therefore, in the setting data, it is clear what types of operation targets are included in each of the operation specifications.

In the creation step, the work instruction sheet is created using the setting data. The use of the setting data makes it possible to accurately reflect the specification information in the preparation step, onto the work instruction sheet.

Preferably, in the method of the present invention, when a change is made in the specification information, the preparation step, the setting step and the creation step are repeated, wherein the setting step includes, when a change is made in the specification information, extracting a change in the operation targets and the operation specification between new and old versions of the setting data.

In this method, when a change is made in the specification information, in the setting step, a change in the operation targets and the operation specification is extracted. Thus, a process can be thoroughly changed according to the change in the specification information.

Preferably, the method of the present invention further comprises a verification step of, after the setting step, verifying efficiency of operation for the operation targets, based on the setting data and using a virtual operation station configured by 3D data, and creating a procedure drawing presenting a operation procedure, based on a result of the verification, wherein the creation step includes creating the work instruction sheet, using the operation specification, the operation targets and the process-related information used in the verification step, and the procedure drawing.

In this method, in the verification step, the verification of operational capability is performed based on the setting data. Thus, the verification can be performed thoroughly for all operation targets set in the setting step. The setting data is created based on the specification information. Thus, the verification will be performed for all operation targets included in the operation specification. Generally, in an actual operation, a situation does not occur in which two or more operations different in operation specification are simultaneously performed for a workpiece. Therefore, when the verification of operational capability is performed for the plurality of operation targets at a time, it is preferable that the plurality of operation targets are included in the same operation specification. Thus, because it is clear what types of operation targets in the setting data are included in each of the operation specifications, it becomes possible to easily verify operational capability of the plurality of operation targets included in the same operation specification. In the verification step, during the verification of operational capability, it is determined what kind of operation procedure can promote operation adequacy. Thus, a operation procedure determined by the verification is created as a procedure drawing. This procedure drawing is necessary for creating the work instruction sheet. It can be said that the verification step is just intended to verify a operation procedure. Therefore, it is efficient to create a procedure drawing during the verification.

In the creation step, the work instruction sheet is created using the operation specification, the operation targets and the process-related information in the verification step, and the procedure drawing. The operation specification, the operation targets and the process-related information are information created through the setting step based on the specification information, which means the work instruction sheet is substantially created based on the setting data. This makes it possible to accurately reflect the specification information in the preparation step, onto the work instruction sheet. Further, the work instruction sheet is created using the procedure drawing created through the verification step. Thus, the procedure drawing reflecting a verification result in the verification step can be appended to the work instruction sheet, and easily associated with the operation specification, the operation targets and the process-related information.

In the above method, the verification step may include adding a non-design-specified operation target which is not included in the operation targets in the specification information, and setting process-related information to the non-design-specified operation target.

According to this feature, operational capability can be verified for operations including a non-design-specified operation which is not set based on the specification information. Thus, the verification of operational capability can be performed in a situation close to an actual operation site, which makes it possible to enhance the accuracy of operational capability.

In the above method, the setting step may include selecting the process-related information to be set with respect to each of the operation targets, from a work instruction sheet database storing a plurality of process-related information settable, respectively, to various types of operation targets; and the verification step may include, based on a result of the verification, correcting the work instruction sheet database.

In this method, setting of the process-related information to each operation target is performed based on the work instruction sheet database. The work instruction sheet database is designed to store the process-related information settable, respectively, to various types of operation targets. There is a possibility that a situation occurs in which, as a result of the verification step or during a course of an actual operation, it becomes necessary to correct the process-related information settable to the operation targets. For example, suppose that a given element operation is originally assigned to a certain operation station under operational capability at that time. In such a situation, according to a verification result in the verification step, it can be determined that it is preferable to perform the elemental operation in other operation station. In this case, in the verification step, the work instruction sheet database is changed, instead of simply changing the process setting data. Thus, the work instruction sheet database as a basis for setting the process-related information can be updated as needed, and subsequently the setting step and other steps can be performed using the updated work instruction sheet database.

In the method of the present invention, the operation may be a painting operation for a vehicle body.

The present invention is also directed to a work instruction sheet creation support system for, in a situation where a plurality of operation specifications is set for a workpiece, creating a work instruction sheet for operation for a plurality of operation targets included in each of the operation specifications. The work instruction sheet creation support system comprises: a client capable of accepting an input from a user and providing an output to a user; a storage device storing a work instruction sheet database having a plurality of process-related information settable, respectively, to various types of operation targets; and a server for performing a given processing, based on information input from the client. The server is operable to, upon receiving, from the client, an input of specification information specifying what types of operation targets are included in each of the operation specifications, generate setting data, using the operation targets and the operation specification, and, after reading, from the work instruction sheet database in the storage device, process-related information settable to the operation targets in the setting data, output the read process-related information to the client, wherein the server is operable to: upon receiving, from the client, an input of selection of either one of the settable process-related information, set the selected process-related information to the operation targets, and, after creating setting data including at least the operation targets, the operation specification and the process-related information, store the setting data in the storage device; and, upon receiving, from the client, an input requesting for the creation of the work instruction sheet, read the setting data from the storage device, and create the work instruction sheet.

In the above system, specification information is prepared which specifies what types of operation targets are included in each of the operation specifications. Thus, even in the case where there are a plurality of types of operation targets, it can be easily recognized what types of operation targets are included in each of the operation specifications. The specification information is a part of design information. As above, the plurality of operation targets are specified with respect to each of the operation specifications. Thus, when any of the operation targets and the operation specification is changed, the change can be easily recognized by comparing operation specifications before and after the change. Further, it becomes possible to easily recognize whether each operation target is a common one among the operation specifications, or is an individual one for each of the operation specifications. If it can be known whether each operation target is a common one or an individual one, the subsequent process setting and theoretical verification can be simplified.

Then, based on the specification information, the process-related information is set with respect to each operation target. Thus, the process-related information can be thoroughly set for all operation targets included in the specification information. Further, the setting data is created based on the specification information. Therefore, in the setting data, it is clear what types of operation targets are included in each of the operation specifications.

Then, the work instruction sheet is created using the setting data. The use of the setting data makes it possible to accurately reflect the specification information onto the work instruction sheet.

Preferably, in the system of the present invention, the server is operable, during generation of the setting data in response to receiving the input of the specification information from the client and when an old version of the setting data is stored in the storage device, to extract a change in the operation targets and the operation specification between new and old versions of the setting data.

In this system, when a change is made in the specification information, a change in the operation targets and the operation specification is extracted. Thus, a process can be thoroughly changed according to the change in the specification information.

The system of the present invention may be configured such that the storage device stores therein a plurality of virtual operation stations each configured by 3D data, wherein the server is operable to, upon receiving, from the client, an input requesting for verification of operational capability on the setting data, after creating the setting data and storing it in the storage device, read one of the virtual operation stations in conformity to the setting data, from the storage device, and output the read virtual operation station to the client to thereby allow the client to perform the verification of operational capability on the setting data, and then store a procedure drawing created based on the verification by the client, in the storage device in a manner associated with the setting data, wherein the server is operable to, upon receiving, from the client, an input requesting for the creation of the work instruction sheet, read, from the storage device, the operation specification, the operation targets and the process-related information used in the verification, and the procedure drawing, and create the work instruction sheet.

In this system, the verification of operational capability is performed based on the setting data. Thus, the verification can be performed thoroughly for all operation targets. The setting data is created based on the specification information. Thus, the verification will be performed for all operation targets included in the operation specification. Generally, in an actual operation, a situation does not occur in which two or more operations different in operation specification are simultaneously performed for a workpiece. Therefore, when the verification of operational capability is performed for the plurality of operation targets at a time, it is preferable that the plurality of operation targets are included in the same operation specification. Thus, because it is clear what types of operation targets in the setting data are included in each of the operation specifications, it becomes possible to easily verify operational capability of the plurality of operation targets included in the same operation specification. During the verification of operational capability, it is determined what kind of operation procedure can promote operation adequacy. Thus, a operation procedure determined by the verification is created as a procedure drawing. Thus, the procedure drawing is created during the verification, and stored in the storage device. This is convenient to subsequently create the work instruction sheet.

Then, the operation specification, the operation targets and the process-related information used for the verification, and the procedure drawing, are read from the storage device to create the work instruction sheet. The operation specification, the operation targets and the process-related information are information created based on the specification information. Thus, it becomes possible to accurately reflect the specification information onto the work instruction sheet. Further, the work instruction sheet is created using the procedure drawing created during the verification. Thus, the procedure drawing reflecting a verification result can be appended to the work instruction sheet, and easily associated with the operation specification, the operation targets and the process-related information.

Preferably, in the above system, the server is operable to: when it operates to allow the client to perform the verification of operational capability on the setting data, read, from the work instruction sheet database in the storage device, a non-design-specified operation target which is not included in the operation targets in the specification information; and add the non-design-specified operation target to the setting data; and read, from the work instruction sheet database in the storage device, process-related information settable to the non-design-specified operation target, and output the read process-related information to the client, wherein the server is operable to: upon receiving, from the client, an input of selection of either one of the settable process-related information, set the selected process-related information to the non-design-specified operation target to thereby allow the client to additionally perform verification of efficiency of operation for the non-design-specified operation target.

According to this feature, operational capability can be verified for operations including a non-design-specified operation which is not set based on the specification information. Thus, the verification of operational capability can be performed in a situation close to an actual operation site, which makes it possible to enhance the accuracy of operational capability.

In the above system, the server may be configured to compare the operation targets and the process-related information used in the verification of operational capability with the work instruction sheet database in the storage device, and, when there is a change therebetween, to output the change to the client.

The work instruction sheet database is designed to store the process-related information settable, respectively, to various types of operation targets. There is a possibility that a situation occurs in which, as a result of the verification step or during a course of an actual operation, it becomes necessary to correct the process-related information settable to the operation targets. For example, suppose that a given element operation is originally assigned to a certain operation station under operational capability at that time. In such a situation, according to a verification result in the verification step, it can be determined that it is preferable to perform the elemental operation in other operation station. In this case, it is preferable that the work instruction sheet database is changed, instead of simply changing the process setting data. Therefore, the system may be configured to output the change to the client to prompt a user to change the work instruction sheet database. Thus, the work instruction sheet database as a basis for setting the process-related information can be updated as needed, and subsequently the process setting and others can be performed using the updated work instruction sheet database.

In the system of the present invention, the operation may be a painting operation for a vehicle body.

### INDUSTRIAL APPLICABILITY

As described above, the present invention is usable in a work instruction sheet creation method and a work instruction sheet creation support system for, in a situation where a plurality of operation specifications is set for a workpiece, creating a work instruction sheet for operation for a plurality of operation targets included in each of the operation specifications.

What is claimed is:

1. A work instruction sheet creation method for, in a situation where a plurality of operation specifications is set for a workpiece, creating a work instruction sheet for operation for a plurality of operation targets included in each of the operation specifications, the method comprising:
a preparation step of preparing specification information specifying what types of operation targets are included in each of the operation specifications;
a setting step of setting, based on the specification information, process-related information with respect to each of the operation targets, to thereby create setting data including at least the operation targets, the operation specification and the process-related information; and
a creation step of creating the work instruction sheet using the setting data.

2. The work instruction sheet creation method as defined in claim 1, wherein:
when a change is made in the specification information, the preparation step, the setting step and the creation step are repeated; and
the setting step includes, when a change is made in the specification information, extracting a change in the operation targets and the operation specification between new and old versions of the setting data.

3. The work instruction sheet creation method as defined in claim 1, which further comprises a verification step of, after the setting step, verifying efficiency of operation for the operation targets, based on the setting data and using a virtual operation station configured by 3D data, and creating a procedure drawing presenting a operation procedure, based on a result of the verification,
wherein the creation step includes creating the work instruction sheet, using the operation specification, the operation targets and the process-related information used in the verification step, and the procedure drawing.

4. The work instruction sheet creation method as defined in claim 3, wherein the verification step includes adding a non-design-specified operation target which is not included in the operation targets in the specification information, and setting process-related information to the non-design-specified operation target.

5. The work instruction sheet creation method as defined in claim 3, wherein:
the setting step includes selecting the process-related information to be set with respect to each of the operation targets, from a work instruction sheet database storing a plurality of process-related information settable, respectively, to various types of operation targets; and
the verification step includes, based on a result of the verification, correcting the work instruction sheet database.

6. The work instruction sheet creation method as defined in claim 1, wherein the operation is a painting operation for a vehicle body.

7. A work instruction sheet creation support system for, in a situation where a plurality of operation specifications is set for a workpiece, creating a work instruction sheet for operation for a plurality of operation targets included in each of the operation specifications, the system comprising:
a client capable of accepting an input from a user and providing an output to a user;
a storage device storing a work instruction sheet database having a plurality of process-related information settable, respectively, to various types of operation targets; and
a server for performing a given processing, based on information input from the client,
wherein the server is operable to:
upon receiving, from the client, an input of specification information specifying what types of operation targets are included in each of the operation specifications, generate setting data, using the operation targets and the operation specification, and, after reading, from the work instruction sheet database in the storage device, process-related information settable to the operation targets in the setting data, output the read process-related information to the client;
upon receiving, from the client, an input of selection of either one of the settable process-related information, set the selected process-related information to the operation targets, and, after creating setting data including at least the operation targets, the operation specification and the process-related information, store the setting data in the storage device; and,
upon receiving, from the client, an input requesting for the creation of the work instruction sheet, read the setting data from the storage device, and create the work instruction sheet.

8. The work instruction sheet creation support system as defined in claim 7, wherein the server is operable, during generation of the setting data in response to receiving the input of the specification information from the client and when an old version of the setting data is stored in the storage device, to extract a change in the operation targets and the operation specification between new and old versions of the setting data.

9. The work instruction sheet creation support system as defined in claim 7, wherein the storage device stores therein a plurality of virtual operation stations each configured by 3D data, and
wherein the server is operable to:
upon receiving, from the client, an input requesting for verification of operational capability on the setting data, after creating the setting data and storing it in the storage device, read one of the virtual operation stations in conformity to the setting data, from the storage device, and output the read virtual operation station to the client to thereby allow the client to perform the verification of operational capability on the setting data, and then store a procedure drawing created based on the verification by the client, in the storage device in a manner associated with the setting data; and,
upon receiving, from the client, an input requesting for the creation of the work instruction sheet, read, from the storage device, the operation specification, the operation targets and the process-related information used in the verification, and the procedure drawing, and create the work instruction sheet.

10. The work instruction sheet creation support system as defined in claim 9, wherein the server is operable to:
when it operates to allow the client to perform the verification of operational capability on the setting data, read, from the work instruction sheet database in the storage device, a non-design-specified operation target which is not included in the operation targets in the specification information, and add the non-design-specified operation target to the setting data;
read, from the work instruction sheet database in the storage device, process-related information settable to the non-design-specified operation target, and output the read process-related information to the client; and,
upon receiving, from the client, an input of selection of either one of the settable process-related information, set the selected process-related information to the non-design-specified operation target to thereby allow the client to additionally perform verification of efficiency of operation for the non-design-specified operation target.

11. The work instruction sheet creation support system as defined in claim 9, wherein the server is operable to compare the operation targets and the process-related information used in the verification of operational capability with the work instruction sheet database in the storage device, and, when there is a change therebetween, to output the change to the client.

12. The work instruction sheet creation support system as defined in claim 7, wherein the operation is a painting operation for a vehicle body.
